(19) United States
(12) Patent Application Publication
(10) Pub. No.: US 2008/0128824 A1
(43) Pub. Date: Jun. 5, 2008

(54) Semiconductor Device and Method for Manufacturing Thereof

(76) Inventor: YONG HO OH, Bupyeong-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/929,840

(22) Filed: Oct. 30, 2007

(30) Foreign Application Priority Data
Dec. 5, 2006 (KR) 10-2006-0121984

(51) Int. Cl. H01L 27/092; H01L 21/3205

(52) U.S. Cl. 257/369; 438/585; 257/E27.062; 257/E21.294

(57) ABSTRACT

A method for manufacturing a semiconductor device and the semiconductor device are provided. A mixed impurity of fluorine and boron are implanted into a polysilicon layer in a PMOS region. The fluorine and boron implanted polysilicon layer is etched to form a gate. The fluorine and boron reaction inhibits infiltration of the boron into a gate oxide film or gate spacer during a subsequent thermal process.

### CROSS-REFERENCE TO RELATED APPLICATION

The present application claims the benefit under 35 U.S.C. §119 of Korean Patent Application No. 10-2006-0121984, filed Dec. 5, 2006, which is hereby incorporated by reference in its entirety.

### BACKGROUND

A typical complementary metal oxide semiconductor (CMOS) semiconductor device often uses polysilicon implanted with impurity for a gate. In addition, as the size of a device becomes smaller, a spike anneal process has been applied in order to form an ultrashallow junction.

Therefore, the activation of a polysilicon gate electrode in an N-type metal oxide semiconductor (NMOS) region using a relatively heavy impurity such as phosphor (P) and the phenomenon of boron penetration in a P-type metal oxide semiconductor (PMOS) region due to a thermal process have both emerged as a problem.

### BRIEF SUMMARY

Embodiments of the present invention provide a polysilicon forming method. Embodiments of the present invention can address the problem of activating the polysilicon gate electrode in the NMOS region and the phenomenon of boron penetration due to the thermal process in the PMOS region so that electrical characteristics of a semiconductor device are improved.

A method for manufacturing a semiconductor device according to an embodiment comprises: stacking a gate oxide film and a polysilicon on a semiconductor substrate on which a PMOS region, an NMOS region, and a device isolating layer are formed; forming a first photoresist pattern exposing the NMOS region on the polysilicon; implanting N-type impurity using the first photoresist pattern as a mask, and removing the first photoresist pattern; forming a second photoresist pattern exposing the PMOS region on the polysilicon; implanting mixed impurity of fluorine and boron using the second photoresist pattern as a mask, and removing the second photoresist pattern; forming a third photoresist pattern exposing a portion of the polysilicon in a region other than the portion where the gate electrode in the NMOS region will be formed and the portion where the gate electrode in the PMOS region will be formed; and forming a polysilicon pattern and a gate oxide film pattern by etching the polysilicon and gate oxide film using the third photoresist pattern as an etch mask.

### BRIEF DESCRIPTION OF THE DRAWINGS

FIGS. 1 to 5 are process views showing a fabricating method of a semiconductor device according to an embodiment of the present invention.

FIGS. 6 and 7 are process views showing a fabricating method of a semiconductor device according to an embodiment of the present invention.

### DETAILED DESCRIPTION

Hereinafter, embodiments of the present invention will be described with reference to the accompanying drawings.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

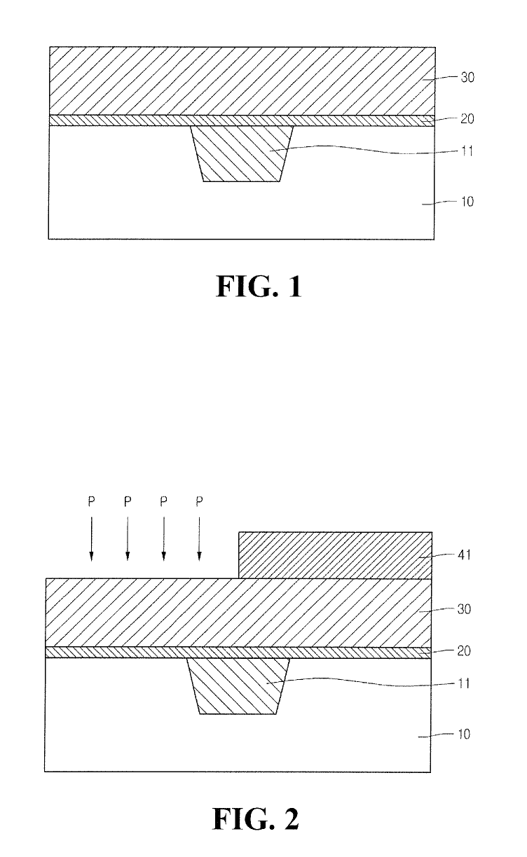

Referring to FIG. 1, a gate oxide film 20 can be formed by oxidizing and growing a surface of a semiconductor substrate 10 on which a device isolating layer 11 is formed. Then, a polysilicon layer 30 can be formed on the gate oxide film 20.

The device isolating layer 11 defines an active region and a device isolating region on the semiconductor substrate. As the forming method for the device isolating layer, a shallow trench isolation (STI) method or a local oxidation of silicon (LOCOS) method can be used. In the embodiment illustrated in FIG. 1, the device isolating layer is formed by means of the STI method.

At one side of the device isolating layer 11 can be an N-type metal oxide semiconductor (NMOS) substrate doped with N-type impurity such as phosphor or arsenic, and at the other side of the device isolating layer 11 can be a P-type metal oxide semiconductor (PMOS) substrate doped with P-type impurity such as boron.

Referring to FIG. 2, a first photoresist film (not shown) can be coated on the polysilicon layer 30. The first photoresist film can be patterned into a first photoresist pattern 41 to expose the NMOS region of the substrate 10.

Then, an N-type impurity such as phosphor (P) or arsenic can be implanted into the NMOS region using the first photoresist pattern as an ion implantation mask. The first photoresist pattern 41 can then be removed and the surface of the substrate can be cleaned.

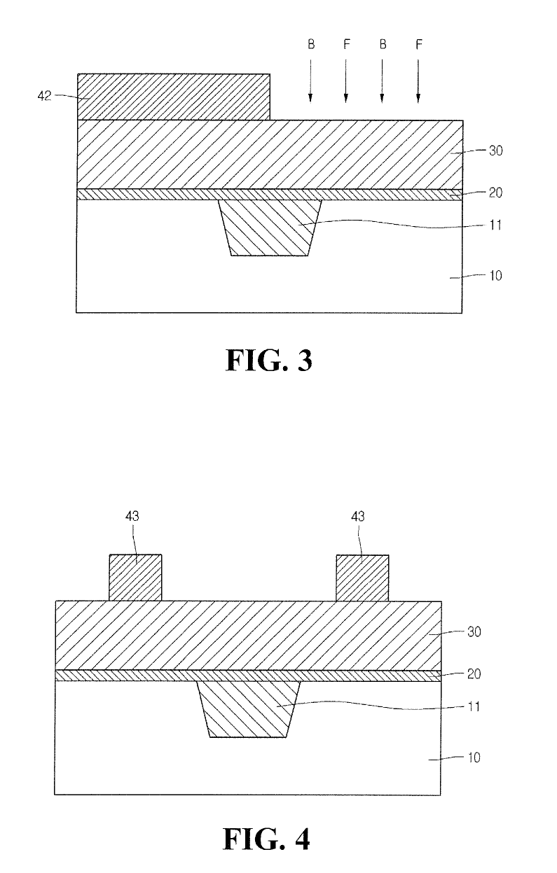

Next, referring to FIG. 3, a second photoresist film can be coated on the polysilicon layer 30. The second photoresist film can be patterned into a second photoresist pattern 42 to expose the PMOS region of the substrate 10.

Then, a mixed impurity of fluorine (F) and boron (B) can be implanted into the PMOS region using the second photoresist pattern as an ion implantation mask. The mixed impurity of fluorine and boron can be implanted at a ratio of 1 to 10 through 1 to 100. In one embodiment, the mixed impurity can include implanting fluorine with a 1×10¹³ ions/cm² to 2×10¹⁴ ions/cm² dose and boron with a 1×10¹⁵ ions/cm² to 2×10¹⁵ ions/cm² dose. Also, the fluorine can be implanted at an implantation energy of about 20 to 40 keV and the boron can be implanted at an implantation energy of about 5 to 10 keV. Then, the second photoresist pattern 42 can be removed and the substrate can be cleaned.

The fluorine is a material capable of effectively inhibiting the diffusion of boron. According to embodiments of the present invention, the infiltration phenomenon of boron from the gate electrode to the circumference thereof that is a problem in the PMOS region can effectively be suppressed by using this property of the fluorine.

That is, the infiltration of boron is inhibited by implanting fluorine together with boron at the time of implanting the P-type impurity ion such as boron into the polysilicon. According to an embodiment of the present invention, the mixed impurity implantation is performed without performing a nitration processing of the gate oxide film. Embodiments utilize the chemical reaction of boron and fluorine, making it possible to effectively suppress the infiltration phenomenon of the boron, which is implanted into the gate polysilicon, into the gate oxide film or a gate spacer in a thermal process such as an annealing process.

Referring to FIG. 4, a third photoresist film (not shown) can be coated on the polysilicon layer 30 and exposed and developed to form a third photoresist pattern 43 exposing the polysilicon in a portion other than where the gate electrode in the NMOS region will be formed and where the gate electrode in the PMOS region will be formed.

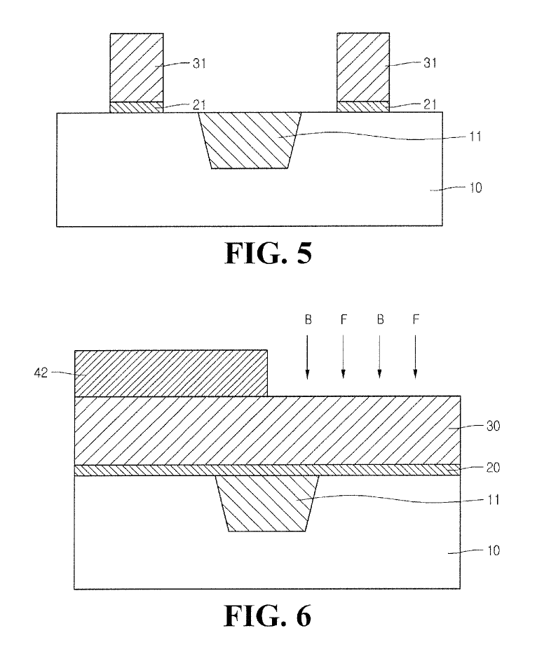

Then, referring to FIG. 5, the polysilicon layer 30 and the gate oxide film 20 can be etched by means of, for example, a reactive ion etching (RIE) using the third photoresist pattern 43 as an etch mask to form a polysilicon pattern 31 and a gate oxide film pattern 21. The third photoresist pattern can then be removed and the substrate can be cleaned.

Thereafter, the semiconductor device can be manufactured by subjecting to the same process as a general CMOS process.

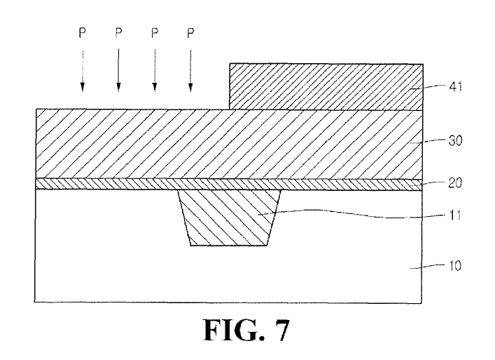

FIGS. 6 and 7 show a method for manufacturing a semiconductor device according to a second embodiment. The method for manufacturing the semiconductor device according to the second embodiment is substantially the same as the first embodiment described above excepting that the PMOS region is first doped with the mixed impurity and then the NMOS region is doped with the N-type impurity by changing the coating order of the first photoresist film and the second photoresist film.

Therefore, the overlapped description of the substantially same components as the first embodiment described above will be omitted, and the same components are denoted with the same term and the same reference number.

First, similarly to the first embodiment, after forming a gate oxide film 20 by oxidizing and growing a surface of a semiconductor substrate 10 on which a PMOS region, an NMOS region, and a device isolating layer are formed, a polysilicon layer 30 can be stacked on the gate oxide film 20.

Then, referring to FIG. 6, a second photoresist pattern 42 exposing the PMOS region can be formed, and the mixed impurity of boron B and fluorine F can be implanted into the PMOS region using the second photoresist pattern 42 as an ion implantation mask. Thereafter, the second photoresist pattern 42 is removed and the substrate can be cleaned. At this time, the mixing ratio of the boron and the fluorine and the process condition may be the same as described with respect to the first embodiment.

Referring to FIG. 7, a first photoresist pattern 41 exposing the NMOS region can be formed, and N-type impurity such as phosphor (P) or arsenic can be implanted into the NMOS region using the second photoresist pattern 41 as an ion implantation mask. Thereafter, the first photoresist pattern 41 is removed and the substrate can be cleaned.

Then, the semiconductor device can be manufactured by performing the processes shown in FIGS. 4 and 5 as described with respect to the first embodiment.

In the semiconductor device according to embodiments of the present invention, the PMOS region, the NMOS region, and the device isolating layer are formed on the semiconductor substrate. And, the first gate oxide film pattern and the first gate electrode implanted with the N-type impurity are formed on the NMOS region. Also, the second gate oxide film pattern and the second gate electrode implanted with the mixed impurity of the fluorine and the boron are formed on the PMOS region.

According to an embodiment, in the second gate electrode, the mixed impurity of the fluorine and the boron may have a mixing ratio of 1 to 10 through 1 to 100 of the fluorine and the boron. Also, the fluorine can be implanted at a 1×10¹³ ions/cm² to 2×10¹⁴ ions/cm² dose and the boron can be implanted at a 10×10¹⁵ ions/cm² to 2×10¹⁵ ions/cm² dose.

With the embodiments as describe above, fluorine is implanted together with boron at the time of implanting the P-type impurity ion so that the poly gate derives the chemical reaction of boron and fluorine to effectively suppress the infiltration phenomenon of the boron into the gate oxide film or a gate spacer in a thermal process, making it possible to improve the whole electrical characteristics of the semiconductor device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, comprising:
stacking a gate oxide film and a polysilicon layer on a semiconductor substrate;
implanting N-type impurity into the polysilicon layer at an NMOS region of the semiconductor substrate;
implanting mixed impurity of fluorine and boron into the polysilicon layer at a PMOS region of the semiconductor substrate; and
etching the impurity implanted polysilicon layer and the gate oxide film to form a polysilicon pattern and a gate oxide film pattern in the NMOS region and the PMOS region.

2. The method according to claim 1, wherein the N-type impurity is phosphor or arsenic.

3. The method according to claim 1, wherein the mixed impurity of the fluorine and the boron has a mixing ratio of 1 to 10 through 1 to 100 (fluorine to boron).

4. The method according to claim 1, wherein implanting the mixed impurity of the fluorine and the boron comprises implanting fluorine at a dose of 1×013 ions/cm² to 2×10¹⁴ ions/cm² and boron at a dose of 1×10¹⁵ ions/cm² to 2×10¹⁵ ions/cm².

5. The method according to claim 4, wherein the fluorine is implanted at an implantation energy of about 20 to 40 keV and the boron is implanted at an implantation energy of about 5 to 10 keV.

6. The method according to claim 1, wherein the etching of the impurity implanted polysilicon layer and the gate oxide film comprises a reactive ion etching process.

7. The method according to claim 1, wherein etching the impurity implanted polysilicon layer and the gate oxide film to form the polysilicon pattern and a gate oxide film pattern comprises:
coating a photoresist on the impurity implanted polysilicon layer;
patterning and developing the photoresist to form a photoresist pattern covering gate electrode regions of both the NMOS region and the PMOS region; and
etching the impurity implanted polysilicon layer and the gate oxide film using the photoresist pattern as an etch mask.

8. A semiconductor device, comprising:
a semiconductor substrate having a PMOS region and an NMOS region;
a first gate oxide film pattern and a first gate electrode comprising N-type impurity on the NMOS region; and
a second gate oxide pattern and a second gate electrode comprising a mixed impurity of fluorine and boron on the PMOS region.

9. The semiconductor device according to claim 8, wherein the mixed impurity of the fluorine and the boron has a mixing ratio of 1 to 10 through 1 to 100 (fluorine to boron).

10. The semiconductor device according to claim 8, wherein the mixed impurity of the fluorine and the boron is a mixed impurity of fluorine at a 1×10¹³ ions/cm² to 2×10¹⁴ ions/cm² dose and boron at a 1×10¹⁵ ions/cm² to 2×10¹⁵ ions/cm² dose.
